(19) United States
(12) Patent Application Publication
(10) Pub. No.: US 2009/0220802 A1
(43) Pub. Date: Sep. 3, 2009

(54) HIGHLY REFLECTIVE LAYER SYSTEM, METHOD FOR PRODUCING THE LAYER SYSTEM AND DEVICE FOR CARRYING OUT THE METHOD

(75) Inventors: Joerg Faber, Mueglitztal Ot Muehlbach (DE); Ekkehart Reinhold, Langebrueck (DE); Carsten Deus, Dresden (DE); Hans-Christian Hecht, Weinboehla (DE); David Schubert, Dresden (DE); Uwe Kralapp, Ottendorf-okrilla (DE); Hendrik Hummel, Dresden Ot Weixdorf (DE)

Correspondence Address: HESLIN ROTHENBERG FARLEY & MESITI PC, 5 COLUMBIA CIRCLE, ALBANY, NY, 12203, US

(73) Assignee: VON ARDENNE Anlagentechnik GmbH, Dresden (DE)

(21) Appl. No.: 12/278,072

(22) PCT Filed: Sep. 6, 2006
(86) PCT No.: PCT/DE06/01561

§ 371 Date: Nov. 20, 2008

(30) Foreign Application Priority Data
Feb. 21, 2006 (DE) 10 2006 008 352.0

(51) Int. Cl. B32B 15/00; C23C 14/28; C25D 11/02; C23C 14/34

(52) U.S. Cl. 428/446; 428/457; 428/702; 428/688; 428/698; 427/585; 205/333; 204/298.23

(57) ABSTRACT

A highly reflective layer system for coating substrates with reflection-enhancing layers, a method for producing the layer system and a device for carrying out the method are provided. On the surface of the substrate, a first functional reflection layer is applied. The first functional reflection layer may be reflective or partially reflective and comprise of metal or a metal alloy which contains one of more constituents from the group comprising copper, nickel, aluminum, titanium, molybdenum and tin. Provided there over is a second functional reflection layer. The second functional reflection later may comprise metal or a metal alloy, for example silver or a silver alloy. Over the second functional reflective layer there follows a first transparent dielectric layer. The first transparent dielectric layer may comprise, for example, silicon oxide. Arranged over the first transparent dielectric layer is a second transparent dielectric layer. This may consist, for example, of titanium oxide.

The invention relates to a highly reflective layer system for coating substrates with reflection enhancing layers, to a method for producing the layer system and to a device for carrying out the method.

In order to improve the reflecting properties of the surfaces of products, it is known to coat these surfaces with thin layers of highly reflective materials. To this end, a variety of methods are used, such as chemical vapor deposition (CVD) with or without plasma enhancement, during which a chemical reaction causes a solid component to be deposited on the hot surface of a substrate during the gas phase, or physical vapor deposition (PVD), where the material, which is to be deposited, exists in a solid form. The PVD methods include, for example, thermal evaporation, sputtering, and ion plating. It is possible with the various PVD variants to deposit nearly all metals and even carbons in a very pure form. If reactive gases, like oxygen, nitrogen or hydrocarbons, are introduced into the process, even oxides, nitrides or carbides can be deposited.

In order to achieve an especially highly reflective surface, the invention provides that a multilayer coating structure is produced on a substrate (S0). In this case the multilayer coating structure comprises at least the following layers:

A first functional reflective layer (S3) is applied to the surface of the substrate (S0), The first functional reflective layer (S3) can be reflective or partially reflective and can consist of metal or a metal alloy, which contains one or more constituent(s) from the group composed of copper, nickel aluminum, titanium, molybdenum, and tin. This first functional reflective layer is provided with a second functional reflective layer (S5). The second functional reflective layer (S5) can be made of metal or a metal alloy, for example silver or a silver alloy. The second functional reflective layer (S5) is provided with a first transparent dielectric layer (S7). The first transparent dielectric layer (S7) can be made, for example, of silicon oxide. The first transparent dielectric layer (S7) exhibits a second transparent dielectric layer (S8). It can be made, for example, of titanium oxide.

According to one embodiment of the invention, a hard material and/or smoothing layer (S1) is/are sandwiched between the substrate (S0) and the first functional reflective layer (S3). The hard material and/or smoothing layer (S1) may be advantageously an oxide layer, which is formed, for example, by anodizing, It may also be advantageous for the hard material and/or smoothing layer (S1) to be a lacquer layer.

According to another embodiment of the invention, an adhesive promoter layer (S2) is sandwiched between the substrate (S0) and the first functional reflective layer (S3). This adhesive promoter layer can be made advantageously of a metal, metal oxide, metal nitride or a mixture of these substances. The adhesive promoter layer (S2) contains advantageously one or more constituent(s) of the group chromium, molybdenum, zinc, titanium tin, aluminum, and silicon. If not only a hard material and/or smoothing layer (S1) but also an adhesive promoter layer (S2) is provided, then the adhesive promoter layer (S2) is disposed advantageously on the hard material and/or smoothing layer (S1), which in turn is disposed directly on the substrate (S0).

According to an additional embodiment of the invention, an adhesive promoter layer (S4) is provided between the first functional reflective layer (S3) and the second functional reflective layer (S5). The adhesive promoter layer (S4) can be made of a metal, metal oxide, metal nitride or a mixture of these substances. The adhesive promoter layer (S4) contains advantageously one or more constituent(s) of the group zinc oxide, titanium oxide, tin oxide, aluminum oxide or silicon oxide.

According to an additional embodiment of the invention, an adhesive promoter layer (S6) is sandwiched between the second functional reflective layer (S5) and the first transparent dielectric layer (S7). The adhesive promoter layer (S6) can be made of a metal, metal oxide, metal nitride or a mixture of these substances. The adhesive promoter layer (S4) contains advantageously one or more constituent(s) of the group zinc oxide, titanium oxide, tin oxide, aluminum oxide or silicon oxide.

According to an additional embodiment of the invention, at least one additional transparent dielectric layer (S9), (S10), etc, is disposed on the second transparent dielectric layer (S8).

According to an additional embodiment of the invention, the first functional reflective layer (S3) is configured so as not to be visually dense, Preferably the thickness of the first functional reflective layer (S3) is at most 90 nm.

According to an additional embodiment of the invention, the first functional reflective layer (S3) and the second functional reflective layer (S5) are configured so as to be together visually dense, Preferably the sum of the thickness of the first functional reflective layer (S3) and the second functional reflective layer (S5) together exceeds 90 nm.

The first functional reflective layer (S3) allows the thickness of the second functional reflective layer (S5) to be reduced without causing any significant loss in the reflectivity of the layer system. As a side effect, this layer design also allows with a suitable choice of the layer material for the first functional reflective layer (S3) the application of the relatively thick second functional reflective layer (S5) by means of electron beam vapor deposition. Therefore, it is no longer necessary to apply, as in the past, the second functional reflective layer (S5) by the conventional magnetron sputtering method.

The inventive layer system makes it possible to manufacture highly reflective surfaces on a plurality of products, which demand such a surface. The range of application of the invention relates to all such products that are explicitly encompassed by the invention. The material of the substrate (S0), which is to be coated, does not exhibit any constraints. However, the inventive layer system can be applied especially advantageously on metal substrates (S0) that are supposed to receive a highly reflective surface.

The inventive method makes it possible to manufacture the inventive layer system on a substrate (S0).

The inventive method for producing a layer system of the above described type provides that the second functional reflective layer (S5) is applied by the electron beam vapor deposition method.

One embodiment of the invention provides that the first transparent dielectric layer (S7) is applied by the electron beam vapor deposition method.

Another embodiment of the invention provides that the second transparent dielectric layer (S8) is applied by the electron beam vapor deposition method.

The inventive device makes it possible to carry out the inventive method and to produce the inventive layer system.

The inventive device, which is intended for producing layer systems on substrates, and in which the substrate, which is to be coated, is moved past a plurality of coating sources, comprises a sequential arrangement of at least a first sputter source, at least a first electron beam vapor source, at least a second sputter source and at least a second electron beam vapor source, said arrangement moving through the device in the transport direction of the substrates.

One embodiment of the invention provides that at least a third sputter source is arranged downstream of the second electron beam vapor source(s).

For example, it can be provided that a group of sputter sources SP1_{—}1 to SP1_x1, a group of electron beam vapor sources EB1_{—}1 to EB1_x2, a group of sputter sources SP2_{—}1 to SP2_x3, a group of electron beam vapor sources EB2_{—}1 to EB2_x4 and finally a group of sputter sources SP3_{—}1 to SP3_x5 are arranged in succession in the transport direction of the substrates. In this case x1, x2, x3, x4 and x5 are whole numbers greater than or equal to 1.

### LIST OF REFERENCE NUMERALS

S0 substrate
S1 hard material and/or smoothing layer
S2 adhesive promoter layer
S3 first functional reflective layer
S4 adhesive promoter layer
S5 second functional reflective layer
S6 adhesive promoter layer
S7 first transparent dielectric layer
S8 second transparent dielectric layer
S9 an additional transparent dielectric layer
S10 an additional transparent dielectric layer

1. Highly reflective layer system for coating substrates wherein the layer system comprises at least the following layers:
first functional reflective layer;
second functional reflective layer;
transparent dielectric layer; and
transparent dielectric layer.

2. Layer system, as claimed in claim 1, wherein the first functional reflective layer comprises metal or a metal alloy.

3. Layer system, as claimed in claim 1, wherein the first functional reflective layer contains one or more constituent(s) from the group consisting of copper, nickel, aluminum, titanium, molybdenum, and tin.

4. Layer system, as claimed in claim 1, wherein the second functional reflective layer comprises metal or a metal alloy.

5. Layer system, as claimed in claim 1, wherein the second functional reflective layer comprises silver or a silver alloy.

6. Layer system, as claimed in claim 1, wherein the first transparent dielectric layer comprises silicon oxide.

7. Layer system, as claimed in claim 1, wherein the second transparent dielectric layer comprises titanium oxide.

8. Layer system, as claimed in claim 1, further comprising a hard material and/or smoothing layer sandwiched between the substrate and a first functional reflective layer.

9. Layer system, as claimed in claim 8, wherein the hard material and/or smoothing layer comprises an oxide layer.

10. Layer system, as claimed in claim 8, wherein the hard material and/or smoothing layer is/are formed by anodizing.

11. Layer system, as claimed in claim 8, wherein the hard material and/or smoothing layer comprises a lacquer layer.

12. Layer system, as claimed in claim 1, wherein a first adhesive promoter layer is sandwiched between a substrate and the first functional reflective layer.

13. Layer system, as claimed in claim 12, wherein the first adhesive promoter layer comprises a metal, metal oxide, metal nitride or a mixture of these substances.

14. Layer system, as claimed in claim 12, wherein the first adhesive promoter layer contains one or more constituent(s) of the group consisting of chromium, molybdenum, zinc, titanium, tin, aluminum, and silicon.

15. Layer system, as claimed in claim 1, wherein a hard material and/or smoothing layer and a first adhesive promoter layer are sandwiched between a substrate and the first functional reflective layer, the first adhesive promoter layer being disposed on the hard material and/or smoothing layer, which in turn is disposed directly on the substrate.

16. Layer system, as claimed in claim 1, wherein a second adhesive promoter layer is sandwiched between the first functional reflective layer and the second functional reflective layer.

17. Layer system, as claimed in claim 16, wherein the second adhesive promoter layer comprises a metal, metal oxide, metal nitride or a mixture of these substances.

18. Layer system, as claimed in claim 16, wherein the second adhesive promoter layer contains one or more constituent(s) of the group consisting of zinc oxide, titanium oxide, tin oxide, aluminum oxide or silicon oxide.

19. Layer system, as claimed in claim 1, wherein a third adhesive promoter layer is sandwiched between the second functional reflective layer and the first transparent dielectric layer.

20. Layer system, as claimed in claim 19, wherein the third adhesive promoter layer comprises a metal, metal oxide, metal nitride or a mixture of these substances.

21. Layer system, as claimed in claim 19, wherein the third adhesive promoter layer contains one or more constituent(s) of the group consisting of zinc oxide, titanium oxide, tin oxide, aluminum oxide or silicon oxide.

22. Layer system, as claimed in claim 1, wherein at least one additional transparent dielectric layer is disposed on the second transparent dielectric layer.

23. Layer system, as claimed in claim 1, disposed on a substrate made of metal or a metal alloy.

24. Method for producing a layer system, as claimed in claim 1, wherein the second functional reflective layer is applied by an electron beam vapor deposition method.

25. Method, as claimed in claim 24, wherein the first transparent dielectric layer is applied by the electron beam vapor deposition method.

26. Method, as claimed in claim 24, wherein the second transparent dielectric layer is applied by the electron beam vapor deposition method.

27. Method for producing a layer system, as claimed in claim 8, wherein the hard material and/or smoothing layer is/are formed by anodizing.

28. Method for producing a layer system, as claimed in claim 8, wherein the hard material and/or smoothing layer is formed by applying a lacquer layer.

29. Device for producing layer systems on substrates, in which a substrate, which is to be coated, is moved past a plurality of coating sources, said device comprising a sequential arrangement of at least a first sputter source, at least a first electron beam vapor source, at least a second sputter source and at least a second electron beam vapor source, said arrangement moving through the device in a transport direction of the substrates.

30. Device, as claimed in claim 29, wherein a third sputter source is arranged downstream of the at least a second electron beam vapor source.
